(19) United States
(12) Patent Application Publication
(10) Pub. No.: US 2010/0055348 A1
(43) Pub. Date: Mar. 4, 2010

(54) DEPOSITION APPARATUS AND DEPOSITION METHOD

(75) Inventors: Terushige TAKEYAMA, Fuchu-shi (JP); Yoshifumi Unehara, Kokubunji-shi (JP); Seiichi Igawa, Fuchu-shi (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/619,786

(22) Filed: Nov. 17, 2009

Related U.S. Application Data
(63) Continuation of application No. PCT/JP2008/059816, filed on May 28, 2008.

(30) Foreign Application Priority Data
May 30, 2007 (JP) 2007-143408

(51) Int. Cl. C23C 16/40; C23C 16/513

(52) U.S. Cl. 427/576; 118/723 R

(57) ABSTRACT

A deposition apparatus for forming a thin film by depositing material particles separated from a deposition material on a deposition object by irradiation with a plasma supplied from a plasma generator into a chamber including a hearth accommodating the deposition material, and a capturing mechanism installed near the hearth and outside the range of a moving region of the material particles moving toward the deposition object. The moving region is determined by a width in an incident direction in which the plasma is incident on the deposition material, and the width of the deposition object 10. The capturing mechanism captures at least some material particles separated from the deposition material and existing outside the range of the moving region.

This disclosure claims priority under 35 U.S.C. §119 to Japanese Application No. 2007-143408, filed May 30, 2007, and under 35 U.S.C. §365 to International Application No. PCT/JP2008/059816, filed May 28, 2008, the contents of which are incorporated herein by reference.

### TECHNICAL FIELD

The present invention relates to a deposition apparatus and deposition method for forming a thin film on a deposition object.

### BACKGROUND ART

A deposition apparatus forms a thin film on a deposition object by a deposition method such as vacuum vapor deposition, sputtering, physical vapor deposition, or chemical vapor deposition.

For example, a deposition apparatus using the ion plating method as one of physical vapor deposition methods includes a plasma generator (plasma source), and generates a plasma beam between a hearth (anode) installed in a low-pressure chamber and the plasma generator. The generated plasma beam irradiates a deposition material placed on the hearth, thereby heating the deposition material. When the deposition material is heated by the plasma beam irradiation, particles of the deposition material (to be referred to as “material particles” hereinafter) evaporate (separate).

In this specification, “material particles” include gaseous or plasma-like particles, that is, molecular particles, atomic group, atomic particles, or charged particles of any of these particles, in addition to a cluster of the material particles, throughout the scope of claims and the drawings. Since the material particles are ionized by the plasma beam, the material particles are attracted to a deposition object at a floating potential, which is relatively negative one with respect to the plasma, and adhere to the surface of the deposition object. Thus, the material particles are deposited on the surface of the deposition object, and form a thin film.

The material particles separated from the deposition material, however, adhere to, for example, the chamber inner wall surfaces and members installed near the hearth other than the deposition object, thereby forming thin films on the chamber inner wall surfaces and the surfaces of these members. In the following explanation, a thin film formed by the material particles adhered to a portion other than the deposition object inside the apparatus will be called an “adhered film”, and distinguished from a thin film formed on the deposition object.

The adhered film grows thick as the operating time of the apparatus increases. The grown adhered film finally peels off. If the peeled adhered film falls and is deposited on the deposition material placed on the hearth, the surface of the deposition material rises. When the surface of the deposition material rises, the plasma beam does not uniformly irradiate the surface of the deposition material any longer. If the surface of the deposition material is not uniformly irradiated with the plasma beam, the direction in which the material particles fly out from the deposition material largely varies. Consequently, no thin film is uniformly formed on the deposition object, and the film quality is adversely affected. This decreases the yield of products.

Generally, the adhered film readily peels off when the operating time of the deposition apparatus exceeds 200 hrs. However, the present inventors have experienced that even before the operating time reaches 200 hrs, the adhered film deposited inside the apparatus peels off if the plasma generator is stopped. This is presumably caused by a temperature change inside the apparatus. The internal temperature of the chamber rises when the plasma generator operates, and lowers when the generator stops. In accordance with this internal temperature change, the chamber inner wall surfaces and the members near the hearth thermally expand and shrink. The adhered film probably peels off because this thermal expansion/shrinkage acts on the adhered film.

In short, the deposition apparatus must continuously be operated in order to prevent peel-off of the adhered film, but the continuous operating time is limited to about 200 hrs. Presently, therefore, the maintenance including, for example, the replacement of the plasma generator and the cleaning of the interior of the apparatus is performed when the continuous operating time has reached approximately 200 hrs.

In deposition by using the deposition apparatus, however, extending the continuous operating time of the deposition apparatus stabilizes the film quality and increases the productivity of the deposition objects (products). Also, the life of the plasma generator is generally 300 hrs.

It is, therefore, desirable to suppress peel-off of the adhered film for a long time period, and prolong the continuous operating time of the deposition apparatus to about 300 hrs.

Accordingly, patent reference 1 has disclosed a technique that forms a metal-sprayed film on the surface of each component in a vacuum deposition apparatus, in order to suppress peel-off of the adhered film. According to patent reference 1, a mechanical bond readily forms between the adhered film and sprayed film because the sprayed film generally has a rough surface. In addition, since the contact area between the sprayed film and adhered film increases, the adhered film hardly peels off. Thus, the peel-off of the adhered film is prevented.

Also, patent reference 2 has disclosed an invention that prevents the adhesion of an organic material to a surface facing a vapor deposition source.

Patent reference 1: Japanese Patent Laid-Open No. 2003-342712
Patent reference 2: Japanese Patent Laid-Open No. 2006-274398

### DISCLOSURE OF INVENTION

### Problems that the Invention is to Solve

Unfortunately, the experiments conducted by the present inventors revealed that peel-off of the adhered film was not sufficiently suppressed even when a metal-sprayed film was formed on each component in a deposition apparatus. Also, the peel-off of the adhered film was observed even before the continuous operating time exceeded 200 hrs.

In addition, when the deposition material is magnesium oxide (MgO), the adhered film formed on the metal-sprayed film peels off together with the metal-sprayed film. This extremely increases the probability that the adhered film peels off before the operating time exceeds 200 hrs.

Note that the peel-off of the adhered film is a common problem that arises not only in the deposition apparatus using the ion plating method described above but also in various deposition apparatuses.

The present invention has been made in consideration of the above-mentioned problem, and has as its object to provide a deposition apparatus capable of capturing at least some material particles causing an adhered film, and preventing the peel-off of the captured material particles for a long time period.

### Means of Solving the Problems

To achieve the above object, a deposition apparatus according to the present invention is a deposition apparatus in which a plasma beam supplied from plasma generating means to a chamber is incident on a deposition material, and material particles separated from the deposition material are deposited on a deposition object, thereby forming a film, characterized by comprising:

deposition material accommodating means for accommodating the deposition material placed in the chamber; and

capturing means for capturing the material particles to a plate member in the chamber by using a mesh member arranged on an incident side of the plasma beam through a predetermined space,

wherein a front surface of the mesh member of the capturing means is located above a region where the deposition material accommodated in the deposition material accommodating means is located, the front surface being positioned within the region at a position in the region which corresponds to a downstream side of the plasma beam so as to oppose the plasma beam.

### EFFECT OF THE INVENTION

The present invention makes it possible to provide a deposition apparatus capable of capturing at least some material particles causing an adhered film, and preventing the peel-off of the captured material particles for a long time period.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is an exemplary sectional view showing an outline of the structure of a deposition apparatus according to an embodiment of the present invention;

FIG. 2A is an exploded perspective view of a capturing mechanism shown in FIG. 1;

FIG. 2B is a side view showing a state in which the capturing mechanism is attached;

FIG. 2C is a perspective view showing the state in which the capturing mechanism is attached; and

FIG. 3 is a perspective view showing a state in which capturing mechanisms are arranged so as to surround a hearth.

### BEST MODE FOR CARRYING OUT THE INVENTION

An embodiment of a deposition apparatus of the present invention will be explained in detail below. However, constituent elements described in this embodiment are merely examples, and the technical scope of the present invention is determined by the scope of claims and is not limited by the following individual embodiment.

In the following explanation, material particles evaporating from a deposition material will particularly be referred to as “metal material particles”. Note that the deposition apparatus of the present invention is not limited to a deposition apparatus using a metal as a deposition material.

A metal film as an object of this embodiment is a material not regarded as a problem in patent reference 2 because adjacent atoms strongly bond to each other and the film hardly peels off from the underlayer.

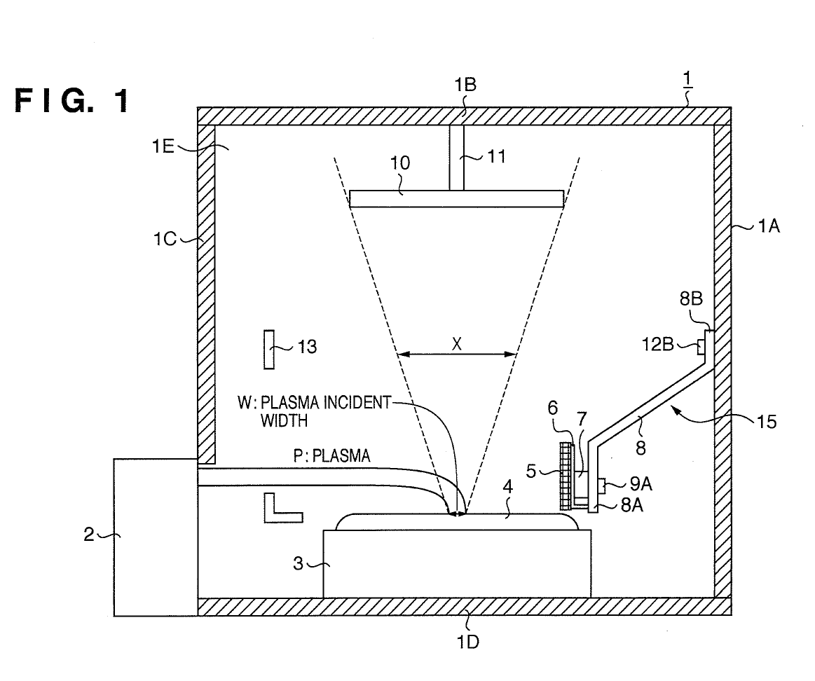

FIG. 1 is an exemplary sectional view showing an outline of the structure of the deposition apparatus of this embodiment. Assume that the deposition apparatus according to this embodiment performs deposition by using the ion plating method as a deposition method. Note that the spirit and scope of the present invention are not limited to the ion plating method as a deposition method, but applicable to another deposition method.

As shown in FIG. 1, the deposition apparatus of this embodiment includes a chamber 1 and plasma generator 2. The chamber 1 is a boxy vessel including a pair of a front portion and back portion, a pair of side portions, and a pair of a ceiling portion and bottom portion. When the deposition apparatus is in operation, the chamber 1 is evacuated and held in a high-vacuum state by an evacuating device (not shown). Note that FIG. 1 shows a pair of a front portion 1A and back portion 1C, a side portion 1E, and a pair of a ceiling portion 1B and bottom portion 1D, and does not show another side portion making a pair with the side portion 1E.

A hearth 3 having a table on which a deposition material 4 is to be placed is installed on the bottom portion 1D of the chamber 1. The deposition material 4 is accommodated in the hearth 3. To simplify the explanation, FIG. 1 shows that the deposition material 4 rises on the hearth 3. Normally, however, the deposition material 4 is completely accommodated in the hearth 3.

The plasma generator 2 is installed in the lower portion of the back portion 1C. The plasma generator 2 generates a plasma P that irradiates the deposition material 4 accommodated in the hearth 3. The deposition material 4 is heated by the irradiation with the plasma P, and metal material particles evaporate from the heated deposition material 4 (the metal material particles separate from the deposition material).

In this apparatus, the plasma generator 2 generates a sheet-like plasma P and irradiates the deposition material 4 with the plasma P. The deposition material 4 has a circular shape. When the deposition material 4 is irradiated with the sheet-like plasma P, that portion of the deposition material 4 along a certain diameter direction is heated, and material particles of the metal (metal material particles) separate from the deposition material 4.

Let W be the width in an incident direction in which the plasma P is incident on the deposition material 4. A region defined by connecting the width W in the incident direction and the width (two ends) of a deposition object 10 will be called a moving region X of the material particles. Since a rotating mechanism (not shown) rotates the deposition material 4 in the hearth 3, the metal material particles uniformly separate from the deposition material 4 when the sheet-like plasma P irradiates the deposition material 4. The separated metal material particles are ionized by the plasma beam irradiation.

The ceiling portion 1B of the chamber 1 has a holding device 11 for holding the deposition object 10. When the deposition apparatus is in operation, a negative voltage is applied to the deposition object 10 held by the holding device 11. Accordingly, many metal material particles separated from the deposition material 4 rise as they are attracted to the deposition object 10 to which the negative voltage is applied, and are adhered and deposited on the surface of the deposition object 10. In this way, a desired thin film is formed on the surface of the deposition object 10.

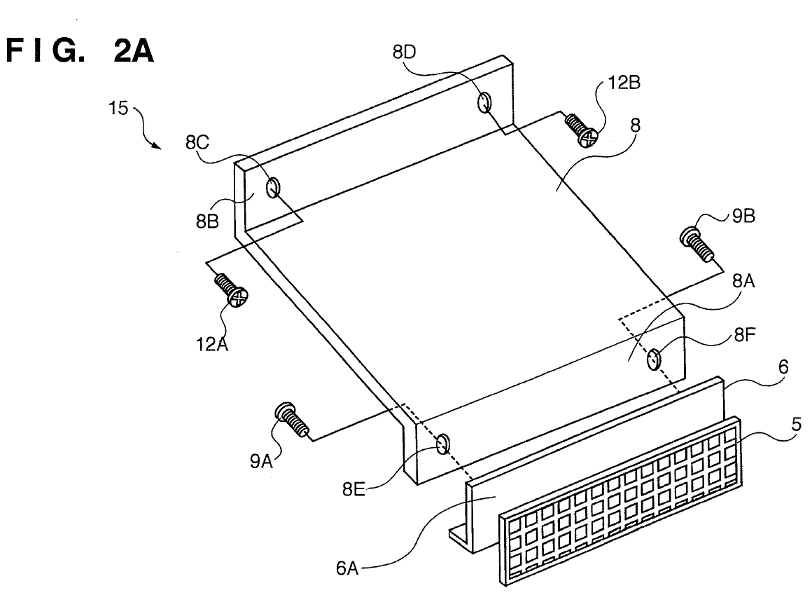

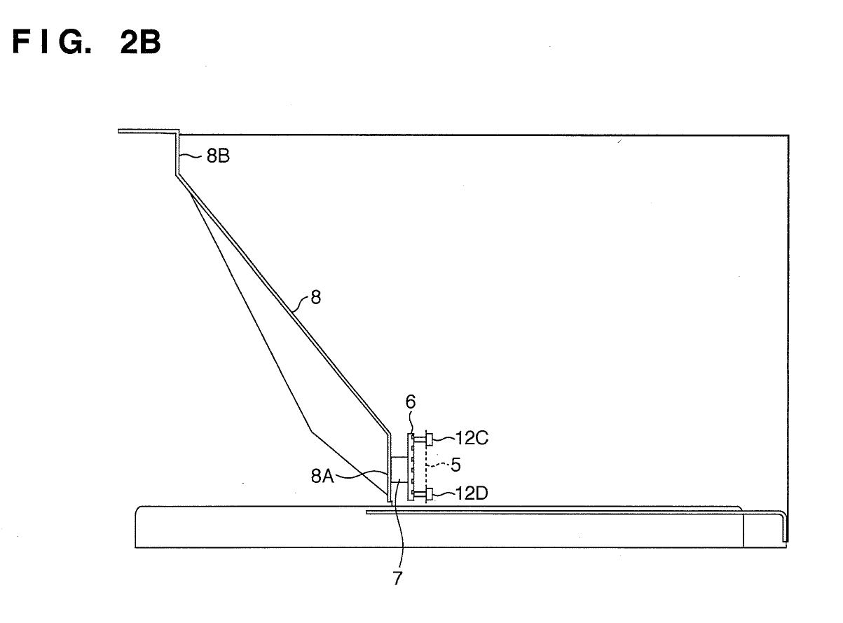

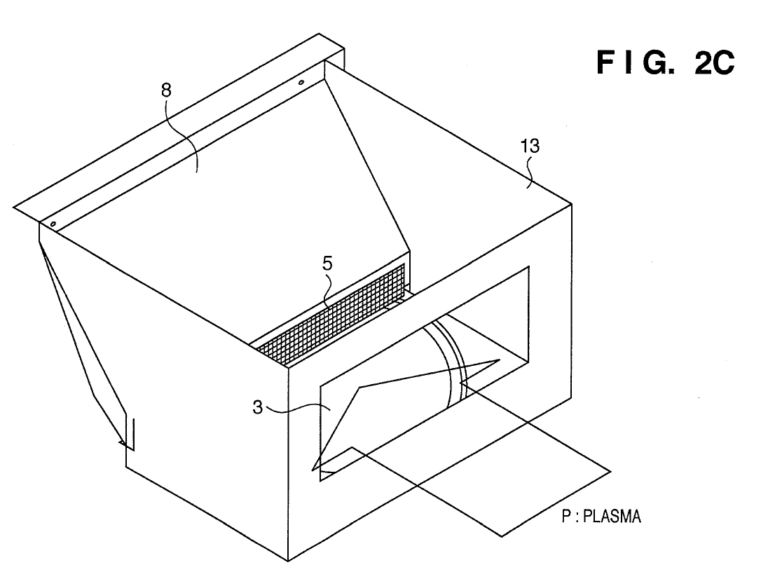

On the other hand, some metal material particles separated from the deposition material 4 do not move upwards in the moving region X toward the deposition object 10, but move in other directions outside the range of the moving region X of the metal material particles. In the deposition apparatus of this embodiment, therefore, a capturing mechanism 15 for capturing the metal material particles moving in the directions outside the range of the moving region X is installed in the chamber 1. The capturing mechanism 15 includes a bracket 8 extending from the front portion 1A of the chamber 1 toward the hearth 3, a capturing plate 6 attached to the distal end of the bracket 8, and a mesh member 5 as a perforated member attached to the surface (a capturing surface 6A (see FIG. 2A)) of the capturing plate 6. The surface (capturing surface 6A) of the capturing plate 6 holds the mesh member 5. In this structure, the capturing plate 6 functions as a holding member for holding the mesh member 5.

FIG. 2A is an exploded perspective view showing the structure of the capturing mechanism 15. The bracket 8 is a plate member having an almost rectangular planar shape, and bracket bent portions 8A and 8B are formed as bent members bent in opposite directions. Holes 8C and 8D are formed in the bracket bent portion 8B. The bracket 8 is detachably fixed to the chamber 1 by threadably engaging screws 12A and 12B inserted into the screw holes (not shown) formed in the front portion 1A of the chamber 1 through the holes 8C and 8D (see FIG. 1).

Referring back to FIG. 2A, the capturing plate 6 is detachably fixed to the bracket bent portion 8A. More specifically, the rear surface (the surface opposite to the bracket bent portion 8A) of the capturing plate 6 has insert nuts 7 (see FIG. 1) for attaching and fixing the capturing plate 6 to the bracket bent portion 8A of the bracket 8. The capturing plate 6 is detachably fixed to the bracket bent portion 8A by threadably engaging screws 9A and 9B inserted into holes formed in the bracket bent portion 8A with the insert nuts 7 through the holes 8E and 8F.

As shown in FIG. 1, the capturing plate 6 attached and fixed to the bracket bent portion 8A of the bracket 8 is positioned outside the range of the moving region X of the material particles in the vicinity of the hearth 3. In other words, the capturing plate 6 is set in the above position by being supported by the bracket 8. More specifically, the capturing plate 6 is held in a region positioned above the hearth 3 and not overlapping the moving region X of the material particles. The length, angle, and the like of the bracket 8 are of course set to enable the capturing plate 6 to be held in the above position.

Referring back to FIG. 2A, the mesh member 5 is fastened by welding or screws to the surface (capturing surface 6A) of the capturing plate 6. Referring to FIG. 2B, the mesh member 5 is fastened to the capturing plate 6 by screws 12C and 12D with a gap being formed between them. A practical arrangement of the mesh member 5 is as follows. For example, metal or resin fibers or wires having a diameter of 1.21 mm are knitted into the form of a lattice, thereby forming a large number of square meshes of 1.33 mm side. The mesh member 5 having these meshes is fastened. However, the shape, dimensions, and the like of the mesh member 5 are not limited to those described above. For example, the same effect is obtained even when the side of the mesh is 0.5 to 3.0 mm. Also, the same effect is obtained even when the diameter of the fibers or wires forming the mesh member 5 is 0.3 to 2.0 mm. Furthermore, the mesh member according to this embodiment of the present invention includes a thin plate having a plurality of holes such as a punching metal.

In either case, a gap having a predetermined distance is formed between the mesh member 5 and the capturing surface 6A of the capturing plate 6 in order to capture the material particles. The area of the mesh member 5 is slightly larger than that of the capturing surface 6A. The predetermined gap is formed between the mesh member 5 and capturing surface 6A by fastening the mesh member 5 to the capturing surface 6A by welding or the screws 12C and 12D while appropriately slacking the mesh member 5. The mesh member 5 and capturing plate 6 may also be fixed by, for example, rivets.

In the deposition apparatus of this embodiment having the above structure, of the metal material particles evaporated from the deposition material 4 by heating by the irradiation with the sheet-like plasma P, most metal material particles moving in directions different from the direction of the deposition object 10 stick to and are captured by the mesh member 5. Furthermore, the metal material particles do not simply stick but are entangled in the mesh member 5. In addition, since the gap is formed between the capturing surface 6A and mesh member 5, the metal material particles enter the gap and are entangled in the mesh member 5. The metal material particles entangled with each other hardly peel off owing to the intermolecular bonding force, compared to metal material particles sticking to a flat surface.

As described above, the capturing plate 6 (mesh member 5) captures most metal material particles moving in directions different from the direction of the deposition object 10, and the captured metal material particles hardly peel off from the mesh member 5. Accordingly, the continuous operating time limit at which an adhered film peels off becomes longer than those of the conventional deposition apparatuses.

Furthermore, the bracket 8 forming the capturing mechanism 15 is detachable from the chamber 1, and the capturing plate 6 is detachable from the bracket 8. This improves the maintenance properties.

Next, a deposition procedure performed by the deposition apparatus including the capturing mechanism 15 described above will be explained below with reference to FIG. 1. When the plasma generator 2 irradiates the deposition material 4 with the sheet-like plasma P, the material particles separate from the deposition material 4, and the separated material particles are adhered to and deposited on the surface of the deposition object 10 set in a position where it faces the deposition material 4. After an evacuating unit (not shown) evacuates the chamber 1 of the deposition apparatus shown in FIG. 1, a transfer unit (not shown) transfers the deposition object 10 to the holding device 11 in the chamber 1, and sets the deposition object 10 on the holding device 11.

The hearth 3 accommodating the deposition material 4 is installed to face the deposition object 10.

Then, the plasma generator 2 generates the plasma P. The plasma P is guided by a magnetic field of a plasma converging unit (not shown) installed near the exit of the plasma P output from the plasma generator 2 and a magnetic field formed by a magnetic field generating unit (not shown) installed on that surface which is opposite to the accommodating surface of the hearth 3 accommodating the deposition material 4 and faces the bottom portion 1D, and is incident on the deposition material 4 in the hearth 3. Note that the hearth 3 is normally maintained at a floating potential, but the plasma generator 2 is maintained at a negative potential. Therefore, the plasma generated from the plasma generator 2 toward the hearth 3 is in a high-energy state.

When the high-energy plasma enters the hearth 3, the material particles are separated from the deposition material 4, and the separated material particles move upwards in the moving region X and are deposited on the deposition object 10, thereby forming a film.

The film thickness can be sensed by, for example, a film thickness sensing unit (not shown). Alternatively, the film thickness can be controlled by the emission timing of the plasma P. When the film is deposited to a desired thickness, the plasma generator 2 stops generating the plasma. The deposition apparatus includes a controller (not shown), and this controller can control the film thickness to be deposited on the deposition object 10.

In this embodiment as shown in FIG. 2C, the mesh member 5 attached and fixed to the capturing plate 6 is positioned above the hearth 3 accommodating the deposition material 4 and downstream in the direction in which the high-energy plasma is supplied from the plasma generator 2 into the chamber 1, so that the mesh member 5 is opposite to the plasma supply direction. Since an adhered film is most vigorously deposited in a portion where the mesh member 5 is placed, the placement of the mesh member 5 shown in FIG. 2C makes it possible to effectively remove the deposition of the adhered film. Note that reference numeral 13 denotes a shield formed around the deposition region.

Subsequently, the transfer unit (not shown) receives the deposition object 10 from the holding device 11, and takes the deposition object 10 out of the chamber 1.

Although plasma is used as the high-energy particles in the above operation, an electron beam made up of electrons may also be used.

Note that even when an 80-mm thick adhered film deposited on the capturing plate 6 of the capturing mechanism 15 during the deposition of MgO, the productivity did not decrease owing to the peel-off of the adhered film. This is a remarkable effect exceeding the prediction of those skilled in the art.

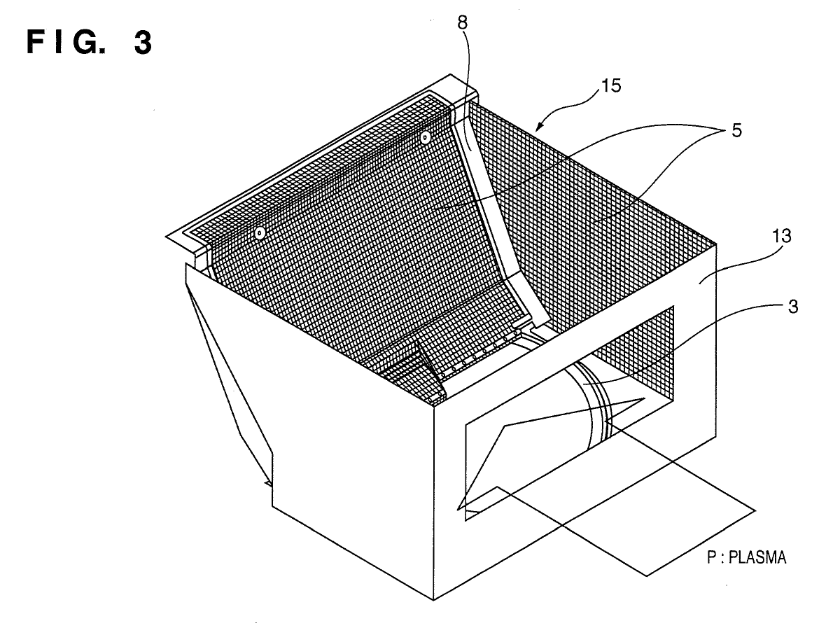

In the above-mentioned embodiment, the apparatus having one capturing mechanism 15 including the mesh member 5 has been explained. However, the number of capturing mechanisms 15 is not limited to one, and a plurality of capturing mechanisms 15 may also be used. For example, as shown in FIG. 3, in a region around the hearth 3 accommodating the deposition material 4 (this region will also be referred to as a “deposition material placement area” hereinafter), it is also possible to arrange a plurality of capturing mechanisms having the mesh members 5 attached to them so as to surround the hearth 3. The mesh members 5 also function as shields surrounding the deposition material placement area, and are attached to surfaces surrounding the deposition material placement area. Alternatively, similar to the bracket 8, one or a plurality of bent capturing mechanisms may also surround the deposition material placement area by the mesh members 5. However, the shapes, positions, dimensions, and the like of the capturing plates are desirably optimized so as not to interfere with the emission of the plasma beam to the placed deposition material or the adhesion of the material particles to the deposition object.

Also, this embodiment has been explained by taking the deposition apparatus using the ion plating method as an example. However, the deposition method is not limited to this example, and the embodiment is also applicable to deposition methods such as sputtering and vacuum vapor deposition. In the ion plating method explained earlier, so-called depo-up by which the deposition material placed below the deposition object 10 facing down deposits on the surface of the deposition object 10 has been explained. However, the spirit and scope of the present invention are not limited to this case. In the sputtering method, it is possible to perform deposition by depo-down by which deposition material particles flying downward are deposited on the surface of the deposition object 10 facing up, or perform deposition such that deposition material particles horizontally flying are deposited on one surface of the deposition object 10 vertically set. In a case like this, the capturing plate and mesh member are preferably arranged near the target and outside the range of the moving region of the material particles.

It is practically possible to solve the problem of the adhered film by installing the capturing mechanism 15 near the portion to which the separated material particles come and outside the moving region of the material particles as described above, without adhering the mesh members 5 on all the inner surfaces of the chamber 1. In addition, the effect of reducing the load of maintenance is obtained because the portion to be replaced is small and lightweight.

This embodiment makes it possible to provide a deposition apparatus capable of capturing at least some material particles that cause the adhered film, and preventing peel-off of the captured material particles for a long time period.

Although the preferred embodiment of the present invention has been explained above with reference to the accompanying drawings, but the present invention is not limited to the embodiment and can be changed into various forms within the technical scope grasped from the description of the scope of appended claims.

The present invention is not limited to the above embodiment, and various changes and modifications can be made without departing from the spirit and scope of the invention. Therefore, to apprise the public of the scope of the present invention, the following claims are appended.

This application claims the benefit of Japanese Patent Application No. 2007-143408, filed May 30, 2007, which is hereby incorporated by reference herein in its entirety.

1-5. (canceled)

6. A deposition apparatus in which a plasma beam supplied from plasma generating means to a chamber is incident on a deposition material, and material particles separated from the deposition material are deposited on a deposition object, thereby forming a film, comprising:
deposition material accommodating means for accommodating the deposition material placed in the chamber; and
capturing means for capturing the material particles to a plate member in the chamber by using a mesh member arranged on an incident side of the plasma beam through a predetermined space,
wherein a front surface of the mesh member of said capturing means is located above a region where the deposition material accommodated in said deposition material accommodating means is located, the front surface being positioned within the region at a position in the region which corresponds to a downstream side of the plasma beam so as to oppose the plasma beam.

7. A deposition method comprising a step of depositing an MgO film using a deposition apparatus defined in claim 6.
